(19) United States
(12) Patent Application Publication
(10) Pub. No.: US 2003/0064326 A1
(43) Pub. Date: Apr. 3, 2003

(54) Resist stripper, resist stripping method, and thin film circuit device formation method

(75) Inventors: Noboru Yamamoto, Kawasaki (JP); Hideya Hashii, Yonago (JP)

Correspondence Address: Patrick G. Burns, Esq., GREER, BURNS & CRAIN, LTD., Suite 2500, 300 South Wacker Dr., Chicago, IL, 60606, US

(73) Assignee: FUJITSU LIMITED

(21) Appl. No.: 10/107,839

(22) Filed: Mar. 27, 2002

(30) Foreign Application Priority Data
Sep. 28, 2001 (JP) 2001-303675

(51) Int. Cl. G03F 7/40; G03F 7/42

(52) U.S. Cl. 430/315; 430/313; 430/328; 430/329; 430/331; 510/176

(57) ABSTRACT

A resist stripper has a composition including a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide, and an amine compound soluble in water. A resist film used and its modified hardened portion are stripped and removed by this resist stripper.

### CROSS-REFERENCE TO RELATED APPLICATIONS

This application is based upon and claims priority of Japanese Patent Application No. 2001-303675, filed on Sep. 28, 2001, the contents being incorporated herein by reference.

### BACKGROUND OF THE INVENTION

1. Field of the Invention

The present invention relates to a resist stripper and resist stripping method necessary to remove a photoresist used in the fabrication of, e.g., semiconductor circuit device patterns.

2. Description of the Related Art

In the fabrication of, e.g., semiconductor devices and liquid crystal display devices, a photoresist is generally used to form a conductive, film, insulating film, and semiconductor film by sputtering or the like, to pattern these films into predetermined shapes, and to dope impurities into predetermined film portions. A photoresist is a protective film which functions as a mask for forming a portion not to be selectively etched, or a portion where no impurities are to be doped. This photoresist consists primarily of a resin, photosensitive agent, and solvent.

Since the solubility characteristics of an exposed portion of the photoresist change, a pattern can be formed by development. By using this resist pattern, a conductive film, insulating film, and semiconductor film exposed to the surface layer are removed by wet etching or dry etching to form a shape corresponding to the resist pattern. After that, the resist pattern which is no longer necessary is removed by a stripping agent.

This resist pattern is desirably completely stripped and removed after it is used. In a process which uses a strong acid or a high-energy plasma in etching of metal alloys and the like, an organic resist stripper is generally used. However, this resist stripper is inferior in stripping properties and shows almost no stripping effect particularly to a modified hardened film of a photoresist produced during the impurity doping step and dry etching step. More specifically, the following problems are found.

Problem 1:

If stripping is incomplete, a photoresist remaining on patterns brings about disconnection, short circuits, and pattern defects, as residues between the patterns while photolithography is repeated several times. This significantly lowers the quality and the yield.

Problem 2:

The only possible countermeasures against a modified hardened film of a photoresist are to reduce the amount of modified hardened film by adding a dry ashing step before stripping, and change the individual conditions in the impurity doping step and dry etching step, e.g., extend the stripping time and raise the temperature.

Problem 3:

A resist stripper having a high amine compound composition ratio has attracted attention to improve the stripping capability of an organic resist stripper. However, because it has a high amine content the resist stripper increases the corrosiveness to metals such as Al and raises the liquid viscosity. Since this lowers the flow rate and pressure of shower or spray in a stripping chamber, system control is difficult to perform.

### SUMMARY OF THE INVENTION

The present invention has been made to solve these problems, and has as its object to provide a resist stripper and resist stripping method having high penetrability even to a modified hardened portion of a resist film produced in, e.g., an impurity doping step or dry etching step, and capable of obtaining a stripping effect equal to or better than that obtained by conditions using a high-amine-content compound, and to provide a thin film circuit device formation method.

To solve the above problems, the present inventors made extensive studies on a resist stripper having good resist stripping properties, no corrosiveness to metals, high liquid stability and safety, and sufficient practicality, and have reached the present invention.

A resist stripper of the present invention has a composition comprising a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide, and an amine compound soluble in water.

A resist stripping method of the present invention comprises the step of stripping and removing at least a modified hardened portion in a surface layer of a resist film by using the above-mentioned resist stripper.

Another aspect of the resist stripping method of the present invention comprises the step of inducing at least an initial dissolution reaction of the resist film by using the above-mentioned resist stripper.

Still another aspect of the resist stripping method of the present invention comprises the steps of irradiating a resist film with ultraviolet radiation, and stripping and removing the resist film by using the above-mentioned resist stripper.

Furthermore, a thin film circuit device formation method of the present invention comprises the steps of forming a thin film selected from the group consisting of an insulating film, conductive film, and semiconductor film on a substrate, forming a resist pattern on the thin film, processing the thin film by using the resist pattern as a mask, and stripping and removing the resist pattern by using a resist stripper according to any one of claims 1 to 5.

Another aspect of the thin film circuit device formation method of the present invention comprises the steps of forming a resist pattern on an object of impurity doping which is a substrate or one of a conductive film and semiconductor film formed on a substrate, doping an impurity into the object of impurity doping by using the resist pattern as a mask, and stripping and removing the resist pattern by using a resist stripper according to any one of claims 1 to 5.

### BRIEF DESCRIPTION OF THE DRAWINGS

FIGS. 1A to 1F are schematic sectional views showing the principal steps of a TFT formation method according to the first formation method of the present invention in order;

FIGS. 2A to 2F are schematic sectional views showing the main steps of a MOS transistor formation method according to the second formation method of the present invention;

FIG. 3 is a graph showing the resist residue generation ratio as a function of the number of defects when substrates having resist patterns used were dipped into resist strippers having different concentration ratios, in the fabrication of TFTs by the first formation method;

FIG. 4 is a graph showing the viscosity as a function of the temperature of a resist stripper;

FIG. 5 is a graph showing the resist stripping residue generation ratios of different resist strippers;

FIG. 6 is a graph showing the results of experiments for examining the Al corrosiveness to an Al alloy film;

FIG. 7 is a graph showing the results of experiments for examining the stripping residue ratio by using thin film circuit device substrates fabricated in FIGS. 1A to 1F;

FIG. 8 is a graph showing the results of experiments in which excimer ultraviolet (UV) processing was added before resist stripping; and

FIG. 9 is a graph showing the results of experiments for checking the viscosity and the stripping residue ratio as functions of the ultraviolet processing time.

### DETAILED DESCRIPTION OF THE PREFERRED EMBODIMENTS

Practical embodiments of the present invention will be described in detail below with reference to the accompanying drawings.

Practical Composition of Resist Stripper

A resist stripper of the present invention contains at least one material selected from N-methyl-pyrrolidone(N-methyl-2-pyrrolidone), N,N-dimethyl-acetamide, dimethyl-formamide, and N,N-methyl-formamide, and an amine compound readily soluble in water, e.g., at least one material selected from N-n-butylethanolamine, diethylaminoethanol, 2-aminoethanol, 2-(2-aminoethylamino)ethanol, 2-ethylaminoethanol, N,N-dimethyl-ethanolamine, N-methyl-diethanolamine, N-ethyldiethanolamine, diethanolamine, di-n-butylethanolamine, triisopropanolamine, 2-methyl-aminoethanol, isopanolamine, N-ethyldiethanolamine, and 2-hydroxyethylamine. Water can be mixed in this resist stripper.

In the resist stripper of the present invention, the amount of highly polar solvent having a viscosity of 2.0 mPa·s or less at 25° C. is 90 to 99 wt %, and the amount of amine compound is 10 wt % or less. The liquid viscosity of the highly polar solvent in a mixed state is 4.0 mPa s or less, and preferably, 3.0 mPa·s or less at 25° C.

Note that this resist stripper is not formed by any special manufacturing method, but is obtained by simply mixing the individual components.

To improve the stripping performance, water or a surfactant can be mixed in this resist stripper. When a surfactant is mixed, fine dust particles can be removed from the surface and stably dispersed in the stripper. This surfactant is desirably a nonionic surfactant containing no metal ions, in order to prevent contamination in various interfaces on the substrate.

Practical Disclosure of Thin Film Circuit Device Formation Methods Including Resist Stripping Methods

Practical methods of forming thin film circuit devices by using a resist stripper having the above composition will be disclosed below.

(First Formation Method)

First, a thin film transistor (TFT) of a liquid crystal display device will be explained as a thin film circuit device.

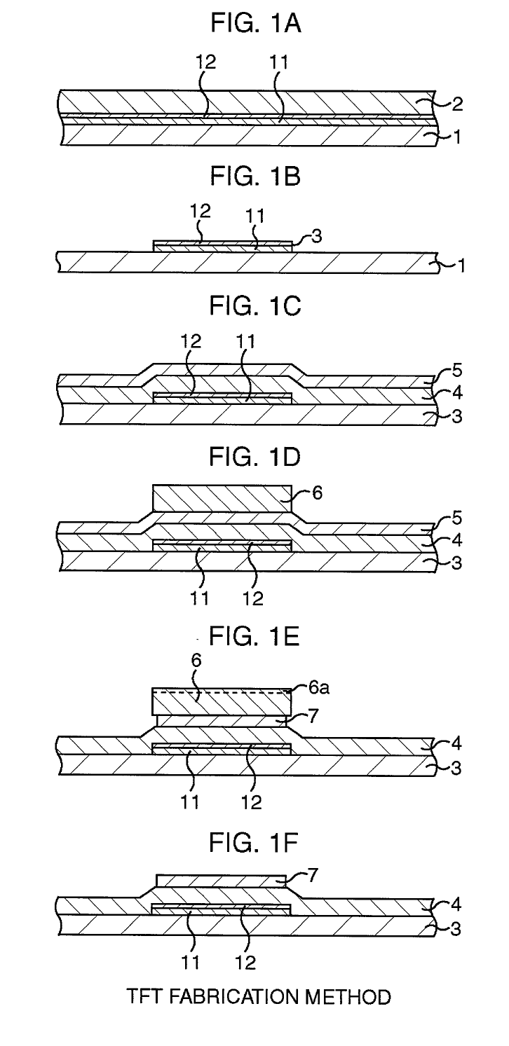

FIGS. 1A to 1F are schematic sectional views showing the major steps of a TFT formation method according to the first formation method in order.

First, as shown in FIG. 1A, an Al film 11 and a Ti film 12 are sequentially formed on a glass substrate 1 by sputtering, thereby forming an Al alloy film. This Al alloy film is coated with a positive photoresist film 2, and this photoresist film 2 is formed into the shape of an electrode by photolithography, thereby forming a resist pattern. Note that a Cr alloy film is sometimes formed instead of an Al alloy film.

Subsequently, as shown in FIG. 1B, the resist pattern is used as a mask to pattern the Al alloy film and form a gate electrode 3. After that, the resist pattern is removed by O₂ dry ashing.

Although the Al alloy film can be patterned by dry etching, it is also preferable to perform wet etching using an etchant containing nitric acid, phosphoric acid, or acetic acid. If a Cr alloy film is formed instead of an Al alloy film, a solution containing ammonium cerium nitrate as its main component is preferably used as an etchant of wet etching.

Next, as shown in FIG. 1C, a silicon nitride film 4 serving as a gate insulating film and an amorphous silicon (a-Si) film 5 serving as an active semiconductor layer are successively formed by plasma chemical vapor deposition.

As shown in FIG. 1D, the a-Si film 5 is coated with a positive photoresist film, and this photoresist film is formed into the shape of an active film by photolithography to form a resist pattern 6.

Subsequently, as shown in FIG. 1E, the resist pattern 6 is used as a mask to pattern the a-Si film 5 by dry etching, thereby forming an active semiconductor film 7. For example, this dry etching is done at a pressure of 37.5 (Pa) and an RF output of 600 (W) for an etching time of 100 sec by using an SF₆/O₂ gas mixture. Consequently, a modified hardened portion 6a is formed in the surface layer of the resist pattern 6 by, e.g., dry etching of the active semiconductor layer 7.

Generally, a resist pattern is difficult to strip and remove after an active semiconductor film of a TFT is formed. As shown in FIG. 1F, therefore, the above-mentioned resist stripper of the present invention is used to strip and remove the resist pattern 6 by wet etching in a predetermined resist stripping apparatus. The processing temperature of the wet etching process is 30° C. to 60° C., in this embodiment 50° C., and a pure water cleaning process is executed after shower processing+air pressure application are performed for 3 min. In place of or in addition to shower processing+air pressure application, dipping, spraying, pressure application, or ultrasonic processing can also be performed.

After that, a TFT is completed through the formation of a dielectric interlayer, contact hole, metal interconnecting layer, and the like.

The resist stripper of the present invention has high penetrability even in the modified hardened portion 6a. Accordingly, a stripping effect equal to or better than that when a stripper containing a high-amine-content compound is used can be obtained not only in an unmodified, unhardened portion of the resist pattern 6 but also in the modified hardened portion 6a.

Note that it is also possible to remove only the modified hardened portion 6a by using the resist stripper of the present invention (e.g., bring about only the initial dissolution reaction), and remove the residual portion by another method (e.g., O₂ ashing).

(Second Formation Method)

A MOS transistor as a semiconductor device will be explained below as a thin film circuit device.

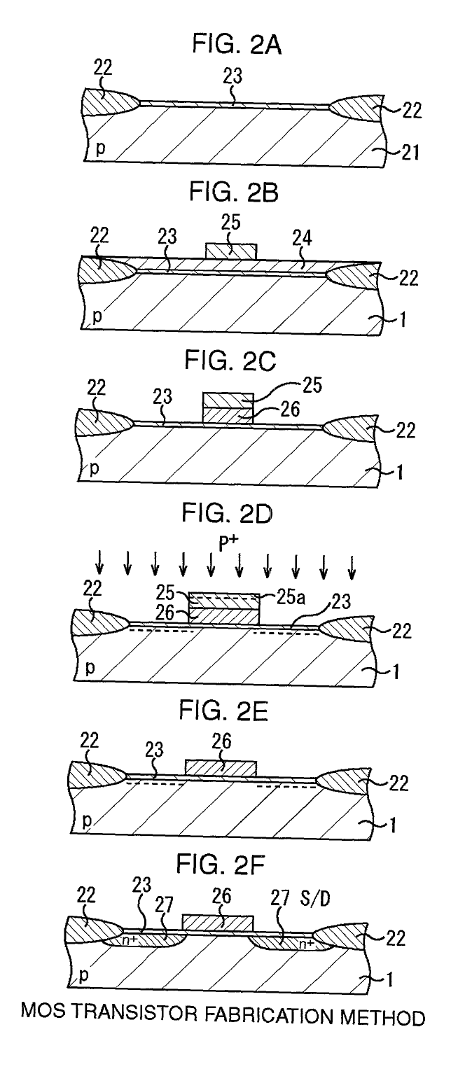

FIGS. 2A to 2F are schematic sectional views showing the major steps of a MOS transistor formation method according to the second formation method.

First, as shown in FIG. 2A, an element region is defined by forming an element isolation region 22 on a p-type silicon semiconductor substrate 21 by LOCOS or the like. After that, a gate insulating film 23 is formed on the surface of the substrate 21 by thermal oxidation.

Subsequently, as shown in FIG. 2B, a polysilicon film 24 is deposited on the entire surface by CVD or the like. This polysilicon film 24 is coated with a positive photoresist, and the photoresist is formed into the shape of an electrode by photolithography, thereby forming a resist pattern 25.

As shown in FIG. 2C, the resist pattern 25 is used as a mask to pattern the polysilicon film 24, forming a gate electrode 26 having a shape corresponding to the resist pattern 25.

As shown in FIG. 2D, the resist pattern 25 is used as a mask again to implant ions of an n-type impurity, in this embodiment phosphorus, into the substrate surface layer on the two sides of the gate electrode 26. Consequently, a modified hardened portion 25a is formed in the surface layer of the resist pattern 25 by dry etching and ion implantation of the polysilicon film 24.

As shown in FIG. 2E, the above-mentioned resist stripper of the present invention is used to perform wet etching in a predetermined resist stripping apparatus, thereby stripping and removing the resist pattern 25. The processing temperature of the wet etching process is 30° C. to 60° C., in this embodiment 50° C., and a pure water cleaning process is executed after shower processing+air pressure application are performed for 3 min. In place of or in addition to shower processing+air pressure application, dipping, spraying, pressure application, or ultrasonic processing can also be performed.

Subsequently, the semiconductor substrate 21 is annealed to form a source/drain 27 in the substrate surface layer on the two sides of the gate electrode 26.

After that, a MOS transistor is completed through the formation of a dielectric interlayer, contact hole, metal interconnecting layer, and the like.

The resist stripper of the present invention has high penetrability even in the modified hardened portion 25a. Accordingly, a stripping effect equal to or better than that when a stripper containing a high-amine-content compound is used can be obtained not only in an unmodified, unhardened portion of the resist pattern 25 but also in the modified hardened portion 25a.

The present invention will be described in more detail below by way of its examples.

### EXAMPLE 1

In this example, N-methyl-2-pyrrolidone and dimethyl-acetamide were used as solvents and mixed with an amine compound (monoethanolamine as primary amine among other amine compounds was used) such that the concentration ratio was 0 to 100 wt %. The resist stripping effects when the resultant solution mixtures were used as resist strippers were examined.

In this example, in the formation of a TFT by the first formation method described earlier, each substrate subjected to the steps shown in FIGS. 1A to 1F was placed in a resist stripping apparatus containing each of the resist strippers at different concentration ratios. After the substrate was processed, measurement was performed by a pattern testing apparatus to obtain the generation ratio of resist residues with respect to the number of defects.

The processing temperature in the resist stripping apparatus was 50° C., and a pure water cleaning process was executed after shower processing+air pressure application were performed for 3 min. The stripping residue generation ratio was calculated by

$$\text{stripping residue} \text{generation ratio} ( \% ) = \text{(number of stripping residues} / \text{number of defects in pattern} \text{testing apparatus)} \times 100$$

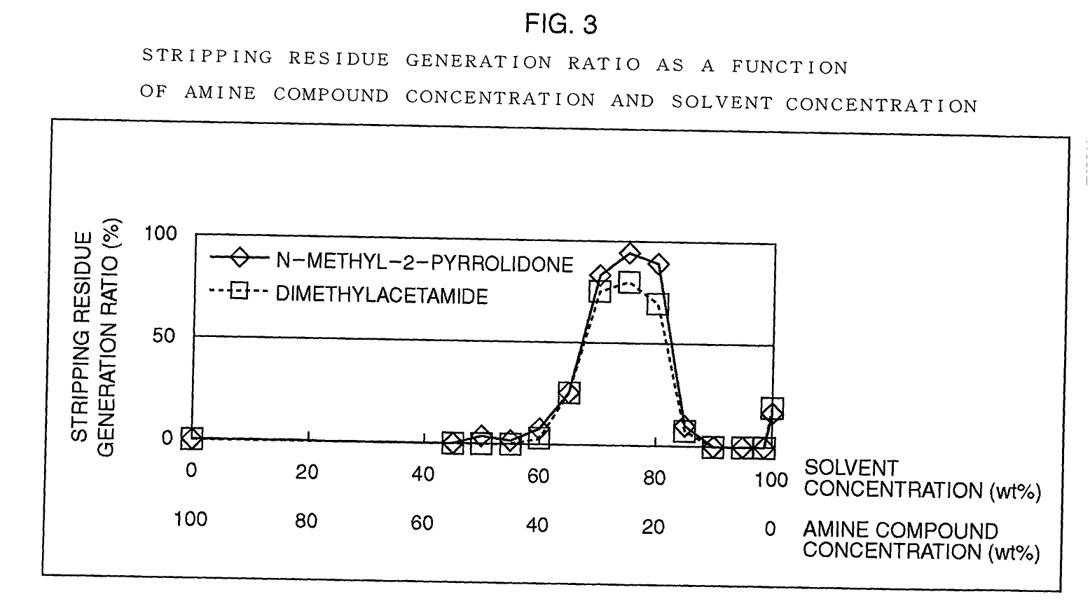

FIG. 3 shows the results of the experiments. The present inventors found that the resist residue generation ratio had two stripping residue peaks.

That is, the resist residue generation ratio was high when the amine compound concentration was 20 to 40 wt % and the solvent concentration was 100 wt %. Abrupt improvements of the resist stripping performance were found when the amine compound ratio was 20 to 2 wt %. When the amine compound ratio was 5 to 2 wt %, the stripping residue ratio was 0%, i.e., a superior stripping effect was obtained.

Also, when N-methyl-2-pyrrolidone and dimethyl-acetamide were 100 wt %, the stripping residue ratio increased.

### EXAMPLE 2

In this example, a conventional stripper (20 wt % of ethanolamine), a commercially available high-amine-content stripper (60 wt % of amine compound), and the resist stripper (a solution mixture of 3 wt % of ethanolamine and 97 wt % of N-methyl-2-pyrrolidone) of the present invention were used to investigate the viscosity and the stripping residue ratio with respect to the stripping temperature, by using thin film circuit device substrates fabricated by the process shown in FIGS. 1A to 1F.

The processing temperature in a resist stripping apparatus was 50° C., and a pure water cleaning process was executed after shower processing+air pressure application were performed for 3 min. The stripping residue generation ratio was calculated by

$$\text{stripping residue} \text{generation ratio} ( \% ) = \text{(number of stripping residues} / \text{number of defects in pattern} \text{testing apparatus)} \times 100$$

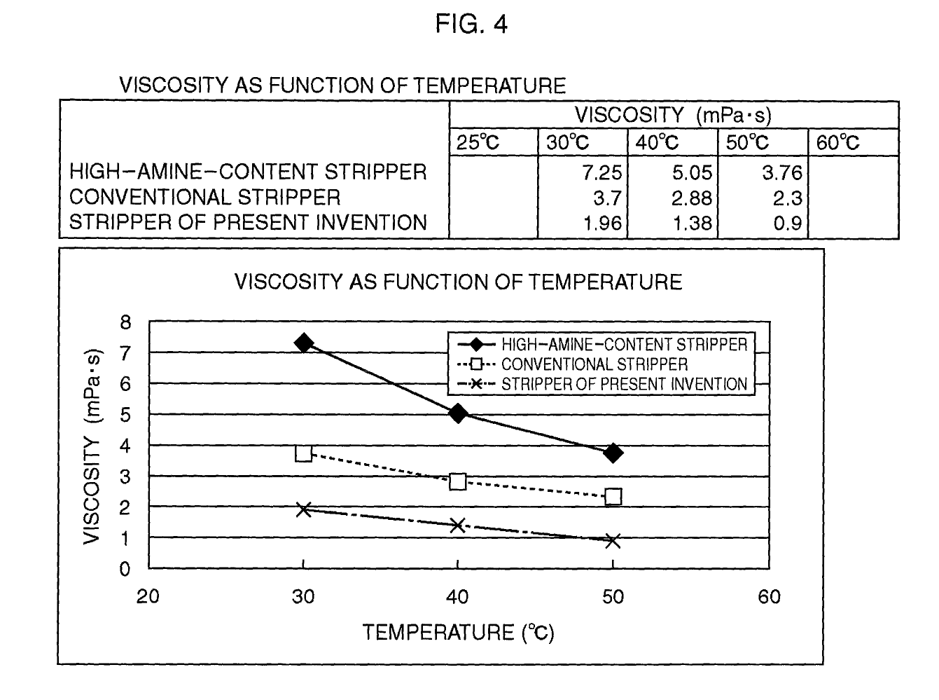

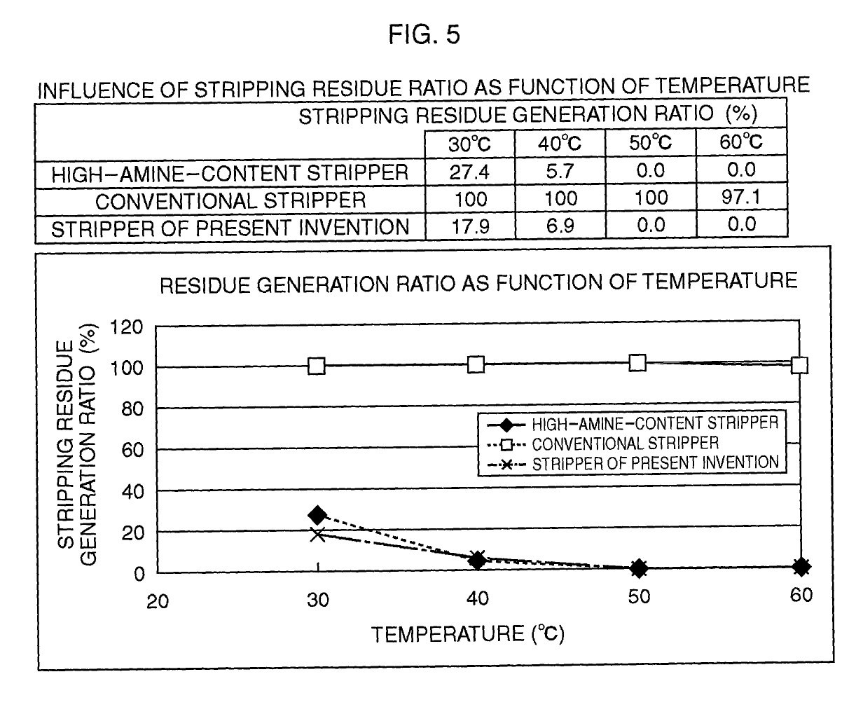

FIG. 4 shows the viscosity as a function of the temperature. FIG. 5 shows the stripping residue generation ratio as a function of the temperature.

The high-amine resist stripper was effective to improve the stripping properties. However, stripping properties equal to or better than those obtained by the high-amine-content resist stripper were obtained by the low-viscosity resist stripper of the present invention.

### EXAMPLE 3

When the amine compound ratio of a resist stripper increases, the stripping performance presumably improves by the generally referred activity of amine. However, a high-amine-content compound undesirably increases the corrosiveness to a metal alloy, so it is necessary to prevent attack to a metal alloy by adding an anticorrosive agent.

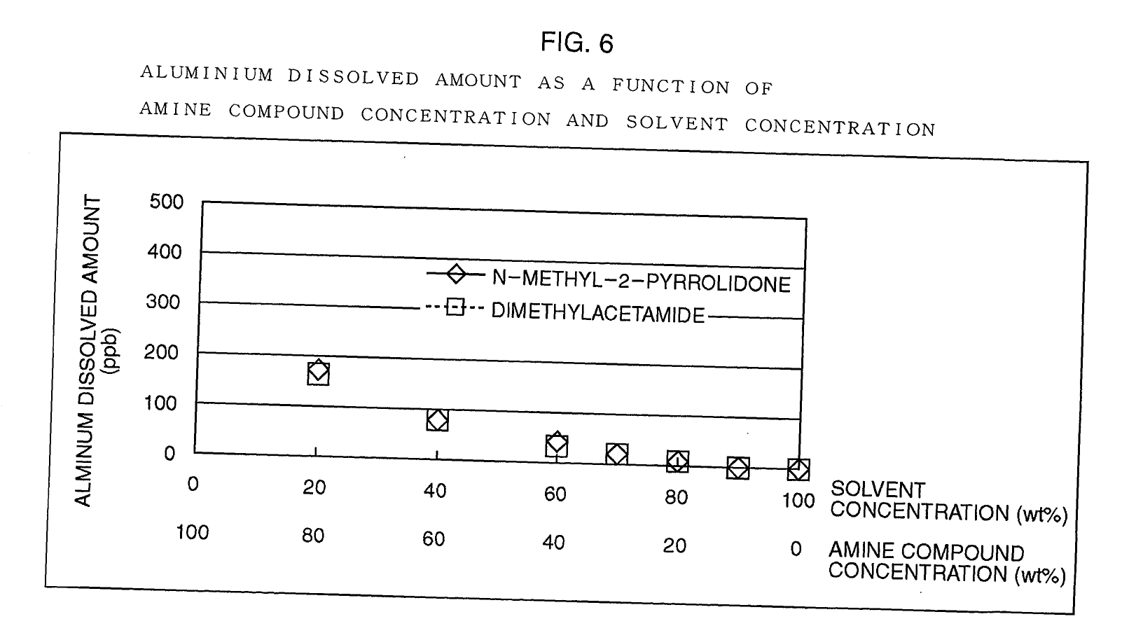

In this example, the Al corrosiveness to an Al alloy film was examined. FIG. 6 shows the results of the experiments.

Pure Al was sputtered on a glass substrate, and the substrate was cut in accordance with prescription. Separately, resist strippers having different concentration ratios were prepared in beakers. Each resist stripper was controlled to 50° C., and each substrate was dipped into the resist stripper for 5 min. The Al dissolved amount in the resist stripper was checked by Al elementary analysis performed by ion chromatography. Note that no anticorrosive agent was mixed in these resist strippers in order to increase the Al dissolved amount.

The Al dissolved amount was found to be a detection limit or less <1 ppm when N-methyl-2-pyrrolidone and dimethyl-acetamide were 90 wt % or more.

If a resist stripping apparatus is not a dipping apparatus but, e.g., a shower or spray apparatus which improves the physical stripping properties, no satisfactory physical stripping properties are difficult to obtain under the influence of viscosity. This makes it difficult to obtain the activity of high amine content.

Also, when the solvent ratio was 100 wt %, the same results were obtained by the two different solvents. Therefore, high stripping performance can be ensured by the addition of a few wt % of ethanolamine. The resist stripper of the present invention has low viscosity and hence is not influenced by viscosity when used by, e.g., shower or spraying which improves the physical stripping properties of a resist stripping apparatus. Accordingly, an excellent resist stripper having no corrosiveness to a metal alloy, particularly Al, can be provided.

Furthermore, since the solvents are highly polar, the resist stripper has a high boiling point and high flash point and is thermally and chemically stable. This reduces resist stripper hazard in handling, so the resist stripper is suitable for use in industrial purposes.

### EXAMPLE 4

In this example, N-methyl-2-pyrrolidone and monoethanolamine were used to prepare two types of resist strippers, i.e., a solution as a resist stripper of the present invention containing 98 wt % of N-methyl-2-pyrrolidone and 2 wt % of monoethanolamine, and a conventional resist stripper having low solubility.

a) The resist stripper of the present invention having the above composition was placed in stripping chamber 1 of a resist stripping apparatus, and the conventional, low-solubility resist stripper was placed in stripping chamber 2. b) The conventional, low-solubility resist stripper was placed in stripping chamber 1, and the resist stripper of the present invention having the above composition was placed in stripping chamber 2. In this way, the effect of stripping performance on a resist modified hardened film was examined in both cases.

That is, experiments were conducted on the stripping residue ratio by using thin film circuit device substrates fabricated by the process shown in FIGS. 1A to 1F.

The processing temperature in the resist stripping apparatus was 50° C., and spray stripping was performed. The processing times were 30, 60, and 120 sec in each of stripping chambers 1 and 2 (the total stripping times in stripping chambers 1 and 2 were 60, 120, and 240 sec, respectively). After the processing, a pure water cleaning process was performed. The stripping residue generation ratio was calculated by

$$\text{stripping residue} \text{generation ratio} ( \% ) = \text{(number of stripping residues} / \text{number of defects in pattern} \text{testing apparatus)} \times 100$$

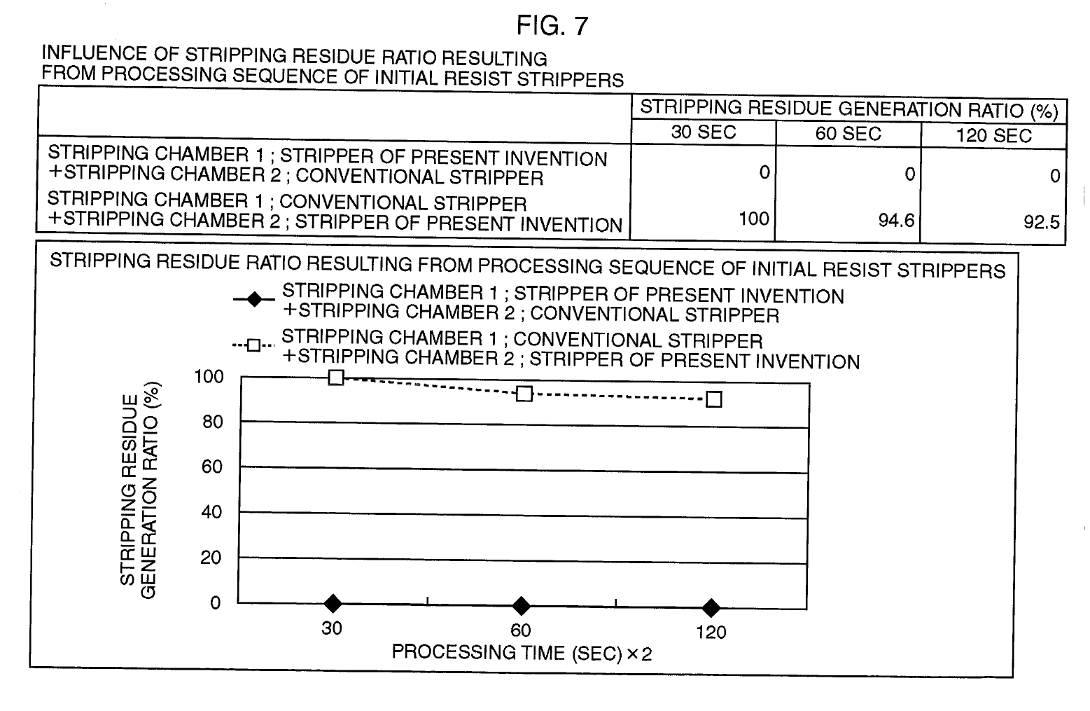

FIG. 7 shows the results of the experiments.

It should be noted that the number of generated resist residues largely changed in accordance with whether a stripper dissolved or did not dissolve an initial resist modified hardened film.

When the resist stripper of the present invention having the above composition was placed in stripping chamber 1 and used to initially dissolve a resist modified hardened film, the film was stripped with no residues left behind regardless of the processing time. In contrast, when the conventional resist stripper having low stripping solubility was used to initially dissolve a resist modified hardened film, the stripping residue ratio improved with the processing time.

This is probably because the resist stripper having low solubility penetrated into the uneven surface layer of a resist modified hardened film, so dissolution progressed while the resist stripper of the present invention placed in stripping chamber 2 gradually replaced the resist stripper that had penetrated into the uneven surface layer.

To sufficiently increase the solubility of the resist stripper of the present invention, therefore, a resist stripping apparatus which initially promotes the dissolution of a resist modified hardened film and a resist film is desired.

### EXAMPLE 5

In this example, experiments in which excimer ultraviolet (UV) processing was added before resist stripping were conducted. As a result, the stripping properties were equivalent to those obtained by the use of the resist stripper of the present invention, as will be described below.

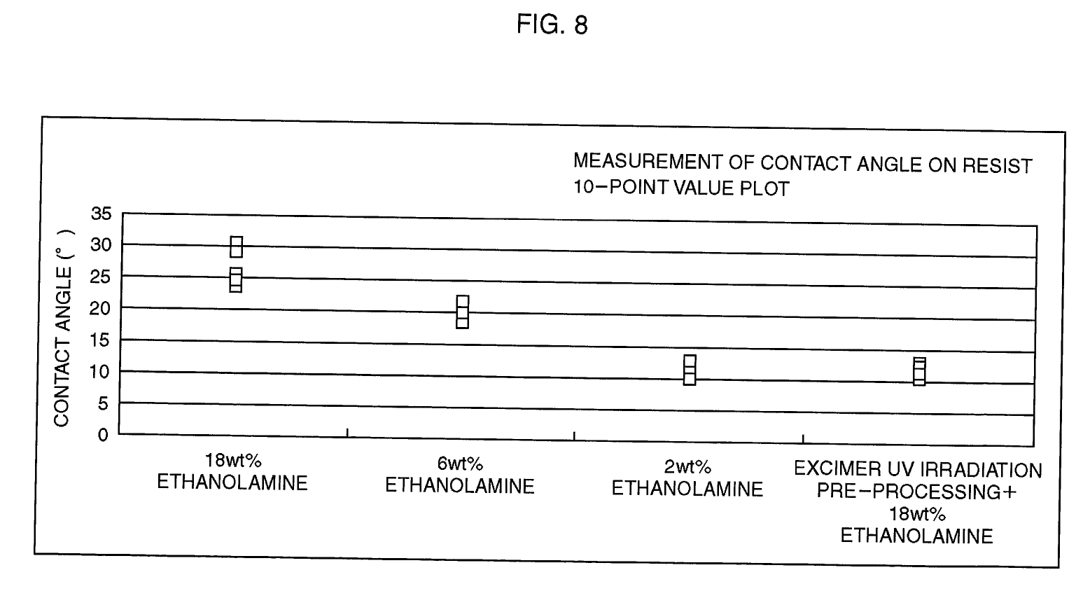

More specifically, as shown in FIG. 8, glass substrates coated with a positive resist film and resist strippers in which the contents of ethanolamine were 18, 6 and 2 wt % and the balance was N-methyl-2-pyrrolidone were used. At room temperature, these resist strippers were dropped onto the resist-coated substrates, and the contact angles were measured with a contact angle measurement apparatus.

Consequently, as the ethanolamine content reduced the contact angle decreased to as small as about 100 Next, a resist-coated substrate was irradiated with excimer UV for 20 sec, and the contact angle was measured on the substrate by using the resist stripper containing 18 wt % of ethanolamine. As a consequence, the contact angle was decreased by about 20° which was near the same contact angle obtained by a solution mixture containing 2 wt % of ethanolamine and 97 wt % of N-methyl-2-pyrrolidone as the resist stripper of the present invention.

Subsequently, the conventional resist stripper (20 wt % of ethanolamine) and the resist stripper (a solution mixture containing 3 wt % of ethanolamine and 97 wt % of N-methyl-2-pyrrolidone) of the present invention were used to check the excimer UV irradiation time and the margin of the resist residue generation ratio. That is, thin film circuit device substrates fabricated by the process shown in FIGS. 1A to 1F were used to conduct experiments on the viscosity and the stripping residue ratio as functions of the stripping temperature.

The processing temperature in a resist stripping apparatus was 50° C., and a pure water cleaning process was executed after shower processing+air pressure application were performed for 3 min. The stripping residue generation ratio was calculated by

$$\text{stripping residue} \text{generation ratio} ( \% ) = \text{(number of stripping residues} / \text{number of defects in pattern} \text{testing apparatus)} \times 100$$

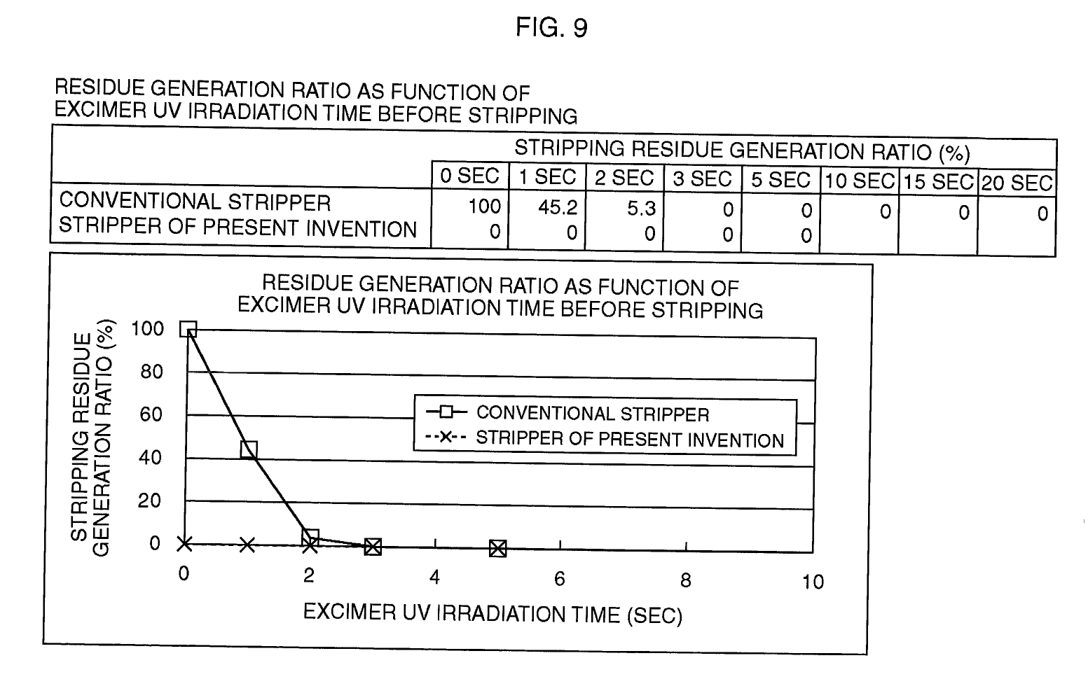

As shown in FIG. 9, resist patterns could be removed with no resist residues when the excimer UV irradiation time was 3 sec or more.

Excimer UV irradiation is also suitable as pre-processing of the stripping step using the resist stripper of the present invention. Since in this case low-temperature processing or short-time resist stripping can be performed in a resist stripping apparatus, the margin of the stripping properties can be further increased.

The resist stripper of the present invention contains a low-viscosity, highly polar solvent as a main component. Since this reduces the molecular weight of the resist stripper, the resist stripper has high penetrability even to a modified hardened portion of a resist film produced in an impurity doping step or dry etching step. Accordingly, it is possible to obtain a stripping effect equal to or better than that obtained by conditions using a high-amine-content compound is used.

What is claimed is:

1. A resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

2. The resist stripper according to claim 1, wherein the viscosity of said highly polar solvent is not more than 2.0 mPa·s at 25° C.

3. The resist stripper according to claim 1, wherein the concentration of said highly polar solvent is 90 to 99 wt %, and the concentration of said amine compound is not more than 10 wt %.

4. The resist stripper according to claim 1, wherein the concentration of said highly polar solvent is 90 to 99 wt %, the concentration of said amine compound is not more than 10 wt %, and the water content is not more than 5 wt %.

5. The resist stripper according to claim 1, wherein the viscosity is not more than 4.0 mPa·s at 25° C.

6. A resist stripping method of stripping and removing a resist film, comprising the step of stripping and removing at least a modified hardened portion in a surface layer of said resist film by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

7. The method according to claim 6, wherein the viscosity of said highly polar solvent is not more than 2.0 mPa·s at 25° C.

8. The method according to claim 6, wherein the concentration of said highly polar solvent is 90 to 99 wt %, and the concentration of said amine compound is not more than 10 wt %.

9. The method according to claim 6, wherein the concentration of said highly polar solvent is 90 to 99 wt %, the concentration of said amine compound is not more than 10 wt %, and the water content is not more than 5 wt %.

10. The method according to claim 6, wherein the viscosity of the resist stripper is not more than 4.0 mPa·s at 25° C.

11. The method according to claim 6, wherein one or a plurality of processes selected from the group consisting of dipping, spraying, pressure application, air pressure application, and ultrasonic processing are combined by using said resist stripper.

12. The method according to claim 6, wherein a processing temperature when said resist stripper is used is 30° C. to 60° C.

13. A resist stripping method comprising the step of stripping and removing a resist film by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

14. The method according to claim 13, wherein the viscosity of said highly polar solvent is not more than 2.0 mPa·s at 25° C.

15. The method according to claim 13, wherein the concentration of said highly polar solvent is 90 to 99 wt %, and the concentration of said amine compound is not more than 10 wt %.

16. The method according to claim 13, wherein the concentration of said highly polar solvent is 90 to 99 wt %, the concentration of said amine compound is not more than 10 wt %, and the water content is not more than 5 wt %.

17. The method according to claim 13, wherein the viscosity of the resist stripper is not more than 4.0 mPa·s at 25° C.

18. The method according to claim 13, wherein one or a plurality of processes selected from the group consisting of dipping, spraying, pressure application, air pressure application, and ultrasonic processing are combined by using said resist stripper.

19. The method according to claim 13, wherein a processing temperature when said resist stripper is used is 30° C. to 60° C.

20. A resist stripping method of stripping and removing a resist film, comprising the step of inducing at least an initial dissolution reaction of the resist film by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

21. The method according to claim 20, wherein the viscosity of said highly polar solvent is not more than 2.0 mPa·s at 25° C.

22. The method according to claim 20, wherein the concentration of said highly polar solvent is 90 to 99 wt %, and the concentration of said amine compound is not more than 10 wt %.

23. The method according to claim 20, wherein the concentration of said highly polar solvent is 90 to 99 wt %, the concentration of said amine compound is not more than 10 wt %, and the water content is not more than 5 wt %.

24. The method according to claim 20, wherein the viscosity of the resist stripper is not more than 4.0 mPa·s at 25° C.

25. The method according to claim 20, wherein one or a plurality of processes selected from the group consisting of dipping, spraying, pressure application, air pressure application, and ultrasonic processing are combined by using said resist stripper.

26. The method according to claim 20, wherein a processing temperature when the resist stripper is used is 30° C. to 60° C.

27. A resist stripping method comprising the steps of:
irradiating a resist film with ultraviolet radiation; and
stripping and removing said resist film by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

28. The method according to claim 27, wherein the viscosity of said highly polar solvent is not more than 2.0 mPa·s at 25° C.

29. The method according to claim 27, wherein the concentration of said highly polar solvent is 90 to 99 wt %, and the concentration of said amine compound is not more than 10 wt %.

30. The method according to claim 27, wherein the concentration of said highly polar solvent is 90 to 99 wt %, the concentration of said amine compound is not more than 10 wt %, and the water content is not more than 5 wt %.

31. The method according to claim 27, wherein the viscosity of the resist stripper is not more than 4.0 mpa·s at 25° C.

32. The method according to claim 27, wherein one or a plurality of processes selected from the group consisting of dipping, spraying, pressure application, air pressure application, and ultrasonic processing are combined by using said resist stripper.

33. The method according to claim 27, wherein a processing temperature when said resist stripper is used is 30° C. to 60° C.

34. A thin film circuit device formation method comprising the steps of:
forming a thin film selected from the group consisting of an insulating film, conductive film, and semiconductor film on a substrate;
forming a resist pattern on said thin film;
processing said thin film by using said resist pattern as a mask; and
stripping and removing the resist pattern by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

35. The method according to claim 34, wherein when said resist pattern is to be stripped and removed, said resist pattern is irradiated with ultraviolet radiation before said resist stripper is used.

36. A thin film circuit device formation method comprising the steps of:
forming a resist pattern on an object of impurity doping which is a substrate or one of a conductive film and semiconductor film formed on a substrate;
doping an impurity into said object of impurity doping by using said resist pattern as a mask; and
stripping and removing said resist pattern by using a resist stripper having a composition comprising:
a highly polar solvent containing at least one member selected from the group consisting of N-methyl-pyrrolidone(N-methyl-2-pyrrolidone), N,N-dimethyl-acetamide, dimethyl-formamide, and N,N-methyl-formamide; and
an amine compound soluble in water.

37. The method according to claim 36, wherein when said resist pattern is to be stripped and removed, said resist pattern is irradiated with ultraviolet radiation before said resist stripper is used.
